(19) United States
(12) Patent Application Publication
(10) Pub. No.: US 2012/0037934 A1
(43) Pub. Date: Feb. 16, 2012

(54) Pre-molded LED light bulb package

(76) Inventor: Han-Ming Lee, Hsinchu City (TW)

(21) Appl. No.: 12/806,490

(22) Filed: Aug. 16, 2010

(51) Int. Cl. H01L 33/52; H01L 33/58

(52) U.S. Cl. 257/98; 257/E33.059; 257/E33.067

(57) ABSTRACT

The present invention relates to a pre-molded LED light bulb package with its main improvements being: the chip and gold wire outside the chip cup at the top of the traditional conducting bracket is covered with an appropriate quantity of epoxy resin colloid and then baked to form an oblate spheroid, which is inserted into the mold and filled with injection PC or ordinary resin to rapidly condense into LED enclosure package, wherein the special effect of multiple amplified or integrated light source whereby the light source is amplified internally and then gathered externally can be achieved by means of an internal optical amplifying light source effect through the pre-molded oblate spheroid and the convex or concave structure on the upper part of the external injection molded LED enclosure, significantly improving the existing single lighting deflection technology, therefore reducing the time of the packaging process and increasing the output capacity of mass production significantly.

### BACKGROUND OF THE INVENTION

As shown in FIG. 1, after the chip and gold wire are inserted into the chip cup at the top of the conducting bracket of the old LED, the old LED must be moved into the mold and filled with epoxy resin, which will dry and harden gradually to form the light bulb; the light given off by the chip at the top is dispersed through the epoxy resin. As the light bulb is totally of the injection epoxy resin structure, the drying process is time-consuming and inconvenient; plus, the conducting bracket must be immediately moved into the mold for mold injection to form the light bulb after its chip and gold wire are inserted; otherwise, the non-packaged chip and gold wire are prone to absorb particles, dust and moisture in the air, therefore reducing the lighting effect and shortening the service life.

### SUMMARY OF THE INVENTION

The primary purpose of the present invention is to provide a pre-molded LED light bulb package, wherein the chip and the gold wire outside the chip cup at the top of the conducting bracket are covered with epoxy resin to form the oblate spheroid, which is filled with injection PC or ordinary resin to rapidly condense into LED enclosure, therefore significantly reducing the time of the packaging process and increasing the output capacity of mass production.

The secondary purpose of the present invention is to provide a pre-molded LED light bulb package, wherein the chip and the gold wire in the chip cup at the top of the conducting bracket are covered with an appropriate quantity of epoxy resin to form the oblate spheroid to generate the internal optical amplified light source effect.

Another purpose of the present invention is to provide a pre-molded LED light bulb package, wherein the upper end of the injection PC or ordinary resin enclosure is of the convex or concave structure to generate the special amplified or integrated light source effect whereby the light source is deflected and amplified internally first and then gathered externally.

### BRIEF DESCRIPTION OF THE DRAWINGS

FIG. 1 shows the schematic of the traditional structure.

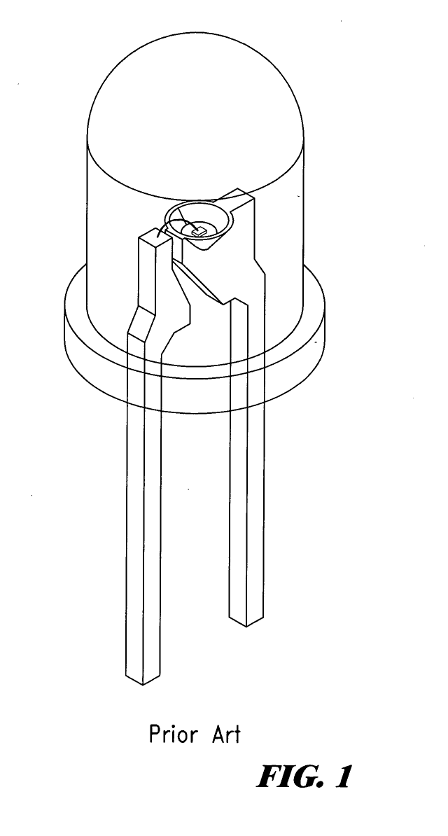

FIG. 2 shows the 3D diagram of the present invention.

FIG. 3 shows the schematic diagram of the components of the present invention.

FIG. 4 shows the schematic diagram of the injection molding procedures of the present invention.

FIG. 5 shows the schematic of the convex function of the shell of the present invention.

FIG. 6 shows the schematic of the concave function of the shell of the present invention.

### DELTAILED DESCRIPTION OF THE PREFERRED EMBODIMENT

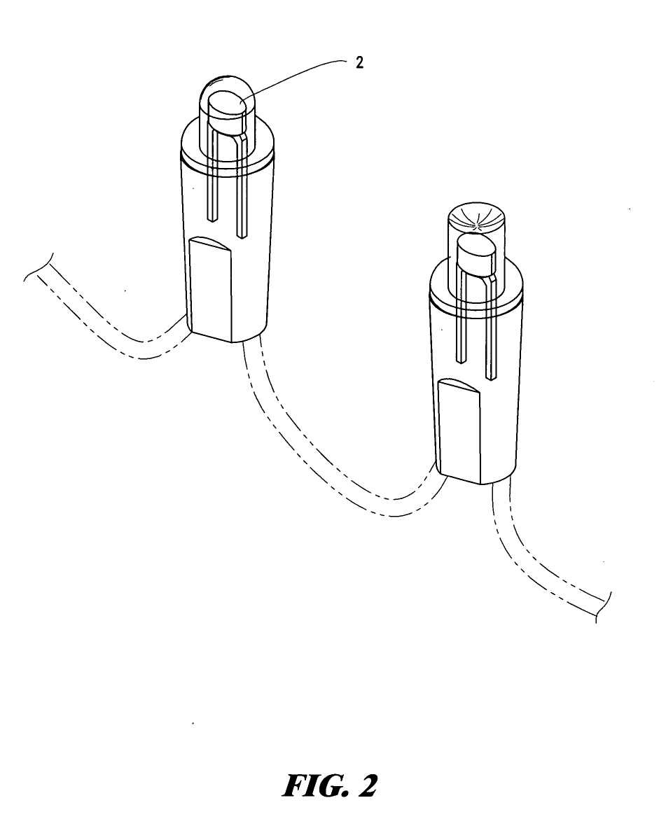

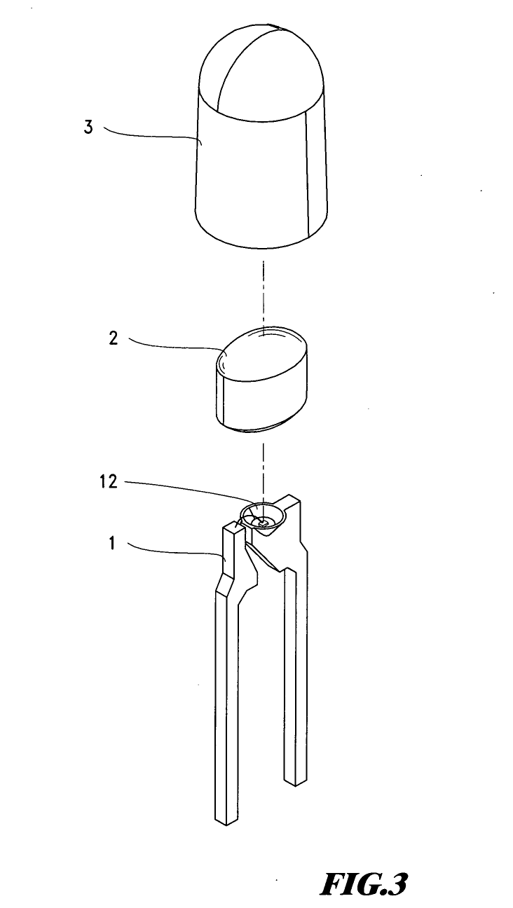

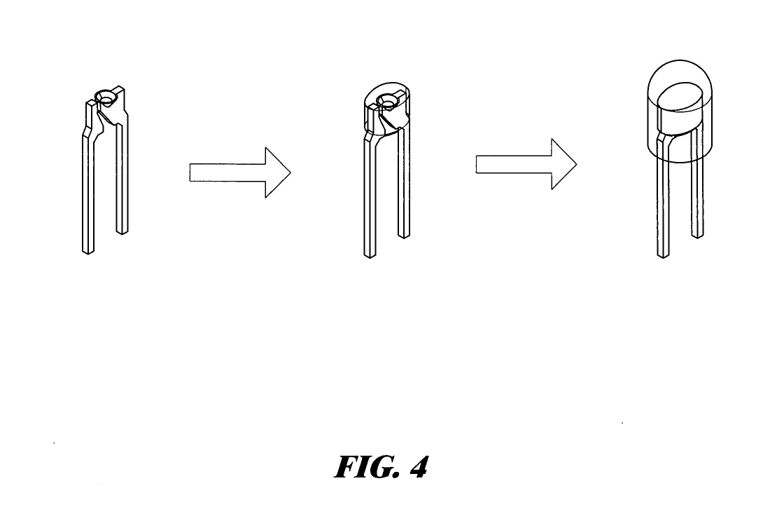

Please refer to FIG. 2 through FIG. 4. The present invention relates to a pre-molded LED light bulb package with its main improvements being: the chip and surrounding of the gold wire in the chip cup (12) at the top of the conducting bracket (1) are covered with an appropriate quantity of epoxy resin colloid in advance, which is baked under the effects of the cohesion of the colloid to naturally form an oblate spheroid (2); the spheroid (2) at the top of the conducting bracket is inserted into the mold and then packaged with injection PC or ordinary resin instead of traditional epoxy resin, which will condense rapidly to form the LED enclosure (3).

In one embodiment of the present invention, the special combination in which the chip and gold wire at the chip cup (12) at the top of the conducting bracket are covered with an appropriate quantity of epoxy resin in advance to form the oblate spheroid permits standardized mass production in advance. In conjunction with the injection PC and ordinary resin injected into the mold to condense rapidly into the LED enclosure (3), the time of the packaging process can be significantly reduced and the output capacity of mass production can be increased.

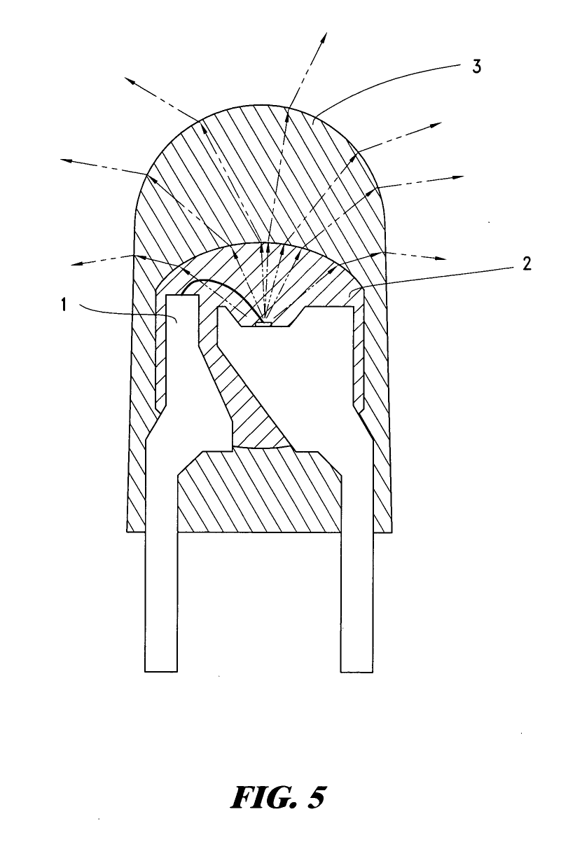

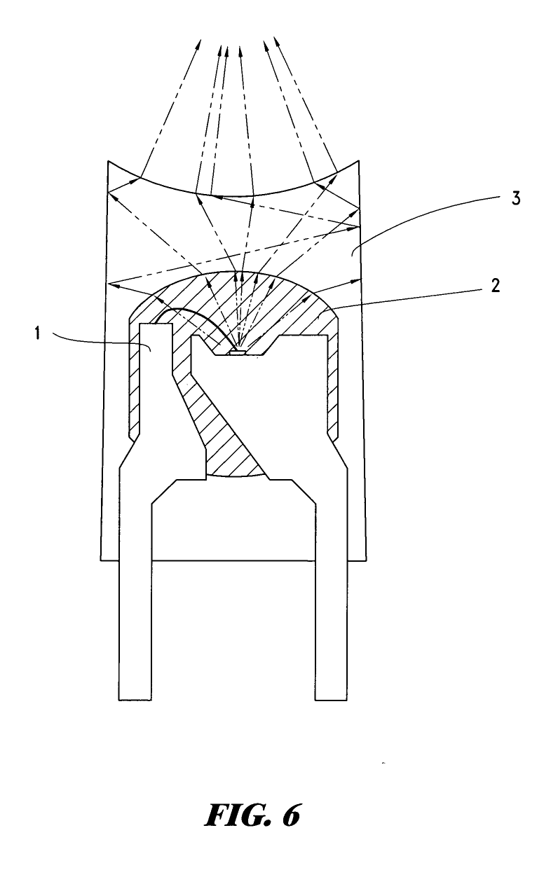

Please refer to FIG. 5 through FIG. 6; the structure of the pre-molded epoxy resin oblate spheroid (2), together with the firm chip and gold wire, generates the internal optical amplified light source effect, and the upper end of the external injection PC or ordinary resin enclosure is of the convex or concave structure to generate the special multiple amplified or integrated light source effect whereby the light source is amplified internally and then gathered externally.

I claim:

1. A pre-molded LED light bulb package with its improvements being: the chip and exterior of the gold wire at the chip cup at the top of the conducting bracket are covered firmly with an appropriate quantity of epoxy resin colloid to form an oblate spheroid that offers the internal optical amplifying light source effect, which is filled with mold injection PC or ordinary resin to condense rapidly into LED enclosure, therefore significantly reducing the time of the packaging process and increasing the output capacity of mass production.

2. The pre-molded LED light bulb package according to claim 1, wherein the upper end of the molded enclosure is of the convex structure, which again generates the multiple amplifying light source effect whereby the light source is amplified internally and then gathered externally.

3. The pre-molded LED light bulb package according to claim 1, wherein the upper end of the molded enclosure is of the concave structure, which again generates the integrated light source effect whereby the light source is amplified internally and then gathered externally.
